(19) United States
(12) Patent Application Publication
(10) Pub. No.: US 2024/0365467 A1
(43) Pub. Date: Oct. 31, 2024

(54) PRINTED CIRCUIT BOARD AND MANUFACTURING METHOD FOR THE SAME

(71) Applicant: SAMSUNG ELECTRO-MECHANICS CO., LTD., Suwon-si (KR)

(72) Inventors: Tae Hong MIN, Suwon-si (KR); Jong Eun PARK, Suwon-si (KR)

(73) Assignee: SAMSUNG ELECTRO-MECHANICS CO., LTD., Suwon-si (KR)

(21) Appl. No.: 18/407,677

(22) Filed: Jan. 9, 2024

(30) Foreign Application Priority Data
Apr. 26, 2023 (KR) 10-2023-0054850
Sep. 7, 2023 (KR) 10-2023-0118778

(51) Int. Cl. H05K 1/03; H05K 1/02; H05K 1/11; H05K 3/46

(52) U.S. Cl. CPC H05K 1/0306; H05K 1/0298; H05K 1/036; H05K 1/115; H05K 3/46; H05K 2201/096; H05K 2201/09827

(57) ABSTRACT

The present disclosure relates to a printed circuit board include: a core layer including an inorganic insulating layer, a resin layer covering at least a portion of an external side surface of the inorganic insulating layer, and a second insulating layer covering at least a portion of a lower surface of each of the inorganic insulating layer and the resin layer and having an interlayer boundary with the resin layer; a first wiring layer disposed on an upper surface of the core layer; and a second wiring layer disposed on a lower surface of the core layer. The external side surface of the inorganic insulating layer is substantially perpendicular to at least one of the upper surface and the lower surface of the inorganic insulating, and a manufacturing method therefor.

### CROSS-REFERENCE TO RELATED APPLICATION(S)

This application claims benefit of priorities to Korean Patent Application Nos. 10-2023-0054850 filed on Apr. 26, 2023 in the Korean Intellectual Property Office, and 10-2023-0118778 filed on Sep. 7, 2023 in the Korean Intellectual Property Office, the disclosure of which are incorporated herein by reference in its entirety.

### TECHNICAL FIELD

The present disclosure relates to a printed circuit board and a manufacturing method for the same.

As market preference has recently changed from the existing portable device-oriented business to a high-capacity server, amounts of data are rapidly increasing and servers, networks, and storage are increasing becoming faster. Accordingly, a new structure substrate with a high multilayer is expanding. As a result, a fan-out multichip module (FOMCM), a fan-out embedded bridge (FOEB), an embedded multi-die interconnect bridge (EMIB) have been developed. On the other hand, in order to respond to a large-capacity server market, many companies are attempting to develop 2.1D as a final goal in a board label, but since layers of a general printed circuit board is basically formed of a high multilayer, and a microcircuit is applied, there is a limit to solving the problem in terms of an actual yield and costs.

### SUMMARY

An aspect of the present disclosure is to provide a printed circuit board that can form a high-density microcircuit with a high yield and low costs, and a manufacturing method therefor.

Another aspect of the present disclosure is to provide a printed circuit board having excellent warpage control and a manufacturing method therefor.

One of the various solutions proposed in the present disclosure is to manufacture a printed circuit board configured by covering an external side surface of an inorganic insulating layer with a resin layer using a frame having a penetration portion, stacking an insulating layer on the inorganic insulating layer and the resin layer, forming a core layer having improved planarization by advancing a planarization process, and forming a wiring layer on the formed core layer.

According to an aspect of the present disclosure, a printed circuit board may include: a core layer including an inorganic insulating layer, a resin layer covering at least a portion of an external side surface of the inorganic insulating layer, and a second insulating layer covering at least a portion of a lower surface of each of the inorganic insulating layer and the resin layer and having an interlayer boundary with the resin layer; a first wiring layer disposed on an upper surface of the core layer; and a second wiring layer disposed on a lower surface of the core layer. The external side surface of the inorganic insulating layer may be substantially perpendicular to at least one of the upper surface and the lower surface of the inorganic insulating layer.

According to an aspect of the present disclosure, a manufacturing method for a printed circuit board may include: disposing an inorganic insulating layer on a penetration portion of a frame having the penetration portion; filling at least a portion of a space between an external side surface of the inorganic insulating layer and a wall surface of the penetration portion with a resin layer; forming a core layer by stacking a second insulating layer on a lower side of the inorganic insulating layer and the resin layer; forming first and second wiring layers on an upper side and a lower side of the core layer, respectively, and removing the frame.

According to an aspect of the present disclosure, a printed circuit board may include: an insulating body in which a glass layer is embedded, and including a plurality of insulating layers disposed on and below the glass layer; a plurality of wiring layers embedded in the insulating body and disposed on and below the glass layer; and a plurality of via layers embedded in the insulating layer and the glass layer to connect the plurality of wiring layers on different levels to each other. A material of the insulating body in contact with a side surface of the glass layer and a material of the insulating body in contact with an upper surface or a lower surface of the glass layer may be different from each other.

One of various effects of the present disclosure is to provide a printed circuit board having a high-density microcircuit with a high yield and low costs and a manufacturing method therefor.

Another of the various effects of the present disclosure is to provide a printed circuit board having excellent warpage control and a manufacturing method therefor.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIG. 4 is a view schematically illustrating a modified example of a printed circuit board of FIG. 3;

FIGS. 5A to 5H are process diagrams schematically illustrating an example of manufacturing the printed circuit board of FIG. 3;

FIGS. 6A and 6B are process diagrams schematically illustrating an example of disposing a plurality of inorganic insulating layers on a frame having a plurality of penetration portions;

FIG. 7 is a cross-sectional view schematically illustrating the other example of a printed circuit board;

FIG. 8 is a view schematically illustrating a modified example of a printed circuit board of FIG. 7;

FIG. 9 is a cross-sectional view schematically illustrating another example of a printed circuit board;

FIG. 10 is a cross-sectional view schematically illustrating a modified example of a printed circuit board of FIG. 9;

FIGS. 11A to 11D are process diagrams schematically illustrating an example of manufacturing the printed circuit board of FIG. 9;

FIG. 12 is a cross-sectional view schematically illustrating another example of a printed circuit board; and

FIG. 13 is a cross-sectional view schematically illustrating a modified example of a printed circuit board of FIG. 9.

### DETAILED DESCRIPTION

Hereinafter, example embodiments of the present disclosure will be described with reference to the attached drawings. The shape and size of the components in the drawings may be exaggerated or reduced for clearer description.

### Electronic Device

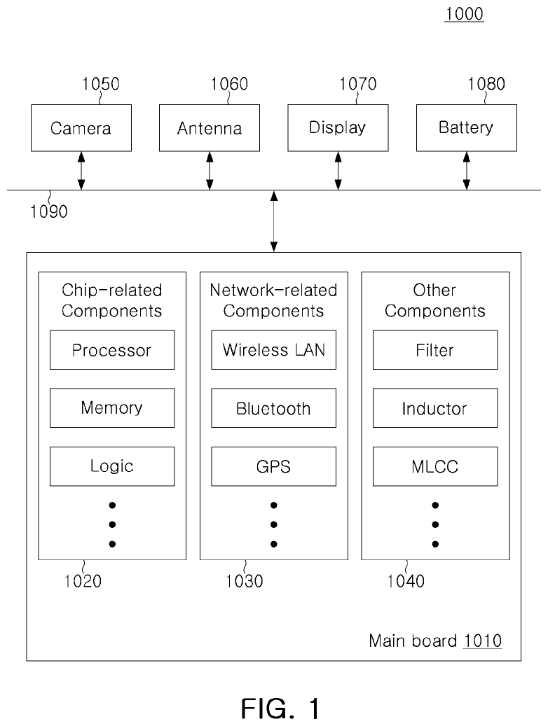

FIG. 1 is a block diagram schematically illustrating an example of an electronic device system.

Referring to FIG. 1, an electronic device 1000 accommodates a main board 1010. Chip-related components 1020, network-related components 1030, and other components 1040 are physically and/or electrically connected to the main board 1010. They are combined with other electronic components described below to form various signal lines 1090.

The chip-related components 1020 may include memory chips such as a volatile memory (e.g., a DRAM), a non-volatile memory (e.g., ROM), and a flash memory; application processor chips such as a central processor (e.g., a CPU), a graphics processor (e.g., a GPU), a digital signal processor, an encryption processor, a microprocessor, and a microcontroller; and logic chips such as an analog-to-digital converter and an application-specific IC (ASIC), but the present disclosure is limited thereto, and the chip-related components 1020 may include other types of chip-related electronic components. Furthermore, these chip-related components 1020 may be combined with each other. The chip-related components 1020 may be in the form of a package including the above-described chips or electronic components.

The network-related components 1030 may include Wi-Fi (such as an IEEE 802.11 family), WiMAX (such as an IEEE 802.16 family), an IEEE 802.20, a long term evolution (LTE), Ev-DO, HSPA+, HSDPA+, HSUPA+, EDGE, GSM, GPS, GPRS, CDMA, TDMA, DECT, a Bluetooth, 3G, 4G, 5G, and any other wireless and wired protocols designated as subsequent, but the present disclosure is not limited thereto, and the network-related components 1030 may include any of a number of other wireless or wired standards or protocols. Furthermore, the network-related components 1030 may be combined with the chip-related components 1020.

Other components 1040 may include a high-frequency inductor, a ferrite inductor, a power inductor, ferrite beads, low temperature co-firing ceramics (LTCC), an electro-magnetic interference (EMI) filter, a multilayer ceramic condenser (MLCC). However, the present disclosure is not limited thereto, and other components 1040 may include a passive element in the form of a chip component used for various other purposes in addition thereto. Furthermore, other components 1040 may be combined with the chip-related components 1020 and/or the network-related components 1030. Depending on the type of electronic device 1000, the electronic device 1000 may include other electronic components that may or may not be physically and/or electrically connected to the main board 1010. Examples of other electronic components include a camera module 1050, an antenna module 1060, a display 1070 and a battery 1080. However, the present disclosure is not limited thereto, and other electronic components may be an audio codec, a video codec, a power amplifier, a compass, an accelerometer, a gyroscope, a speaker, a mass storage device (e.g., a hard disk drive), a compact disk (CD), and a digital version disk (DVD). Additionally, the electronic device 1000 may include other electronic components used for various purposes depending on the type of electronic device 1000.

Examples of the electronic device 1000 include a smartphone, a personal digital assistant, a digital video camera, a digital still camera, a network system, a computer, a monitor, a tablet, a laptop, a netbook, a television, a video game, a smart watch, and an automotive component. However, the present invention is not limited thereto, and the electronic device 1000 may be any other electronic device that processes data in addition thereto.

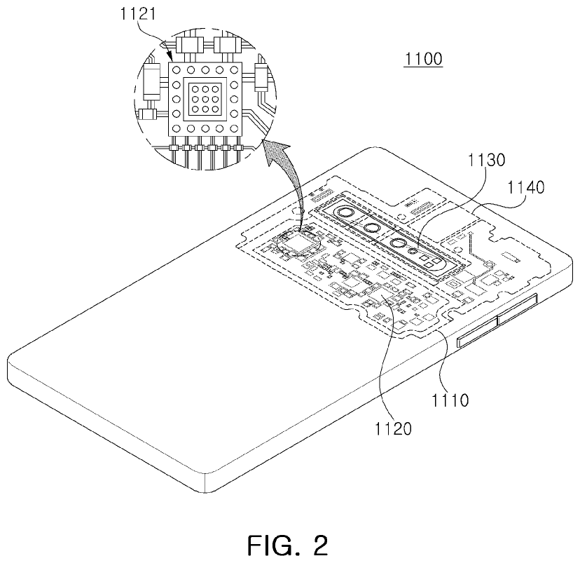

FIG. 2 is a perspective view schematically illustrating an example of an electronic device.

Referring to FIG. 2, the electronic device may be, for example, a smartphone 1100. A motherboard 1110 is accommodated in the smartphone 1100, and various components 1120 are physically and/or electrically connected to the motherboard 1110. Furthermore, other components that may or may not be physically and/or electrically connected to the motherboard 1110 such as a camera module 1130 and/or a speaker 1140 are accommodated inside. Some of the components 1120 may be chip-related components described above, for example, a component package 1121, but the present disclosure is not limited thereto. The component package 1121 may be in the form of a printed circuit board in which an electronic component including an active component and/or a manual component is surface-mounted. Alternatively, the component package 1121 may be in the form of a printed circuit board in which an active component and/or a manual component is embedded. Meanwhile, the electronic device is not necessarily limited to the smartphone 1100, and may be other electronic devices as described above.

### Printed Circuit Board

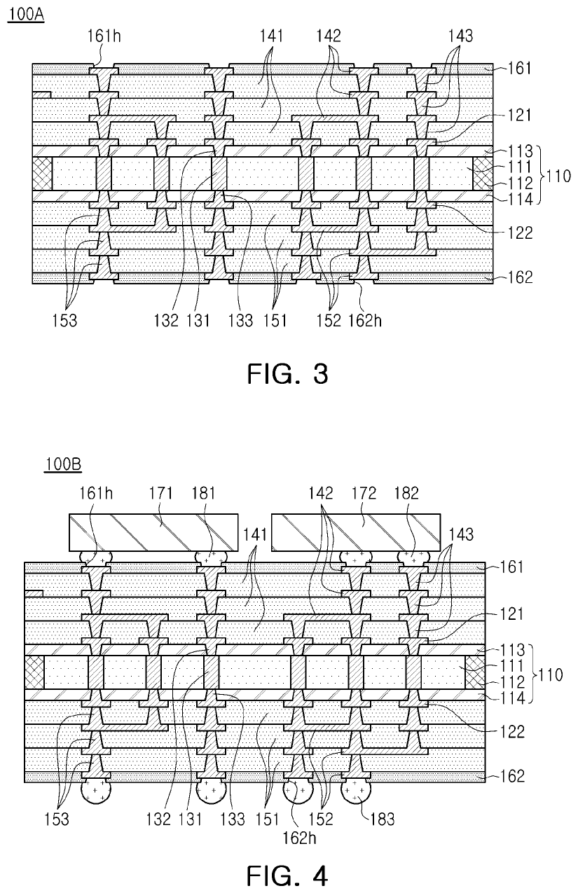

FIG. 3 is a cross-sectional view schematically illustrating an example of a printed circuit board.

According to FIG. 3, a printed circuit board 100A may include a core layer 110 including an inorganic insulating layer 111, a resin layer 112 covering an external side surface of the inorganic insulating layer 111, a first insulating layer 113 covering an upper surface of each of the inorganic insulating layer 111 and the resin layer 112, and a second insulating layer 114 covering at least a portion of a lower surface of each of the inorganic insulating layer 111 and the resin layer 112, a first wiring layer 121 disposed on an upper surface of the core layer 110, and a second wiring layer 122 disposed on a lower surface of the core layer 110. The external side surface of the inorganic insulating layer 111 may be substantially perpendicular to the upper surface and/or the lower surface of the inorganic insulating layer 111. The resin layer 112 may have an interlayer boundary with the first and second insulating layers 113 and 114, respectively.

As described above, since the printed circuit board 100A according to an example embodiment includes the core layer 110 that includes an inorganic insulating layer 111, it may basically have excellent planarization, and may also be advantageous for warpage control through a low coefficient of thermal expansion (CTE). Furthermore, as in a process described below, the core layer 110 may be manufactured through a manufacturing process using a frame, and may have a vertical external side surface of the inorganic insulating layer 111, and the external side surface may not be externally exposed by being covered by the resin layer 112. Furthermore, because the first and second insulating layers 113 and 114 are stacked on the inorganic insulating layer 111 and the resin layer 112, planarization may be further improved, so that it may be more advantageous to form high-density microcircuits having fine pitches. Furthermore, the number of layers of a printed circuit board 110A may be reduced and the degree of design freedom may be further increased through dielectric characteristics of the inorganic insulating layer 1 for example, when the inorganic insulating layer 111 includes glass, the characteristics of glass having variable properties of Dk 2.5 to 11. Through the printed circuit board 100A, a flip chip board (FCB) substrate on a 2.xD level may be easily manufactured.

Meanwhile, an upper surface of the inorganic insulating layer 111 and an upper surface of the resin layer 112 may be substantially coplanar with each other, and a lower surface of the inorganic insulating layer 111 and a lower surface of the resin layer 112 may be substantially coplanar with each other. Accordingly, the first and second insulating layers 113 and 114 may be stacked by minimizing undulation, and the first and second wiring layers 121 and 122 including microcircuits may be more easily formed on the first and second insulating layers 113 and 114.

Meanwhile, the resin layer 112 may include an organic insulating material different from those of the first and second insulating layers 113 and 114. For example, the resin layer 112 and the first and second insulating layers 113 and 114 may be layers that are physically and materially separated from each other. For example, the resin layer 112 may fill a penetration portion of the frame as in a process described below, and may include an underfill or an epoxy molding compound (EMC), but the present disclosure is not limited thereto. On the other hand, the first and second insulating layers 113 and 114 may be layers for forming the first and second wiring layers 121 and 122, and may include an Ajinomoto build-up film (ABF), a photoimageable dielectric (PID), and/or a bonding sheet (BS), but the present disclosure is not limited thereto.

On the other hand, the printed circuit board 100A may further include a through-via 131 penetrating through the inorganic insulating layer 111, a first connection via 132 penetrating through the first insulating layer 113, connected the first wiring layer 121 and coming into contact with an upper surface of the through-via 131, and a second connection via 133 penetrating through the second insulating layer 114, connected to the second wiring layer 122, and coming into contact with a lower surface of the through-via 131. For example, since adhesion force is difficult to secure on the upper surface and the lower surface of the inorganic insulating layer 111, a wiring layer including a pad pattern may not be directly formed thereon. A side surface of the through-via 131 may be substantially perpendicular to an upper surface and/or a lower surface of the through-via 131, but the present disclosure is not limited thereto, and the side surface thereof may be tapered like an hourglass shape if necessary. The first and second connection vias 132 and 133 may be tapered in opposite directions.

On the other hand, the printed circuit board 100A according to an example embodiment may further include one or more first build-up insulating layers 141 disposed on the upper surface of the core layer 110 and covering the first wiring layer 121, one or more first build-up wiring layers 142 disposed on or in the one or more first build-up insulating layer 141, respectively, one or more first build-up via layers 143 penetrating through at least one of the one or more first build-up insulation layers 141 and connected to at least one of the one or more first build-up wiring layers 142, respectively, one or more second build-up insulating layers 151 disposed on the lower surface of the core layer 110 and covering the second wiring layer 122, one or more second build-up wiring layers 152 disposed on or in the one or more second build-up insulating layers 151, and one or more second build-up via layers 153 penetrating through at least one of the one or more second build-up insulation layers 151 and connected to at least one of the one or more second build-up wiring layers 152, respectively. The first and second build-up insulating layers 141 and 142 may have the same number of layers. One or more first and second build-up via layers 143 and 153 may be tapered surfaces in opposite directions. For example, the printed circuit board 100A may be a 2.xD level FCB substrate having a substantially symmetrical structure.

Meanwhile, the printed circuit board 100A according to an example embodiment may include a first resist layer 161 disposed on the one or more first build-up insulating layers 141 and having one or more first openings 161h each exposing an uppermost first build-up wiring layer among the one or more first build-up wiring layer 142, and a second resist layer 162 disposed on the one or more second build-up insulation layers 151 and having one or more second openings 162h each exposing a lowermost second build-up wiring layer of the one or more second build-up wiring layers 152.

Hereinafter, referring to the drawings, components of the printed circuit board 100A according to an example will be described in more detail.

The inorganic insulating layer 111 may include an inorganic insulating material. The inorganic insulating material may be, for example, glass or silicon. For example, the inorganic insulating layer 111 may include a glass layer or a silicon layer. The glass layer may include glass which is an amorphous solid. Glass may include, for example, pure silicon dioxide (about 100% SiO₂), soda lime glass, borosilicate glass, and alumino-silicate glass. However, the present disclosure is not limited thereto, and alternative glass materials such as fluorine glass, phosphate glass and chalcogen glass may also be used as materials for the insulating inorganic layer 111. Furthermore, other additives may be further included to form glass with specific physical properties. These additives may include calcium carbonate (e.g., lime) and sodium carbonate (e.g., soda), as well as magnesium, calcium, manganese, aluminum, lead, boron, iron, chromium, potassium, sulfur and antimony, and carbonate and/or oxides of these elements and other elements. The glass layer is a layer distinguished from materials including glass fibers (Glass Fiber, Glass Cloth and Glass Fabric), for example, copper clad laminate (CCL) and Prepreg (PPG), and may be understood as plate glass. The silicon layer may include pure silicon (Si). If necessary, the silicon layer may include an oxide layer formed on silicon (Si). The oxide layer may include a silicon oxide film, but the present disclosure is not limited thereto.

The resin layer 112 may include an organic insulating material. The organic insulating material may be a thermosetting resin such as an epoxy resin, and a thermoplastic resin such as polyimide. If necessary, the resin layer 112 may further include an inorganic filler and/or an organic filler. For example, the resin layer 112 may include a known underfill resin or an epoxy molding compound (EMC), but the present disclosure is not limited thereto.

Each of the first and second insulating layers 111 and 112 may include an organic insulating material. The organic insulating material may include a thermosetting resin such as an epoxy resin, a thermoplastic resin such as polyimide, or materials including an inorganic filler, an organic filler, and/or glass fibers (Glass Fiber, Glass Cloth, Glass Fabric) along with these resins. For example, the insulating material may be a non-sensitive insulating material such as an Ajinomoto build-up film (ABF) or Prepreg (PPG), but the present disclosure is not limited thereto, and other polymer materials may be used. Furthermore, the insulating material may be a photosensitive insulating material such as a photoimageable dielectric (PID). Furthermore, the insulating material may include an adhesive sheet such as a bonding sheet (BS).

Each of the first and second wiring layers 121 and 122 may include a metal. The metal may include copper (Cu), aluminum (Al), silver (Ag), tin (Sn), gold (Au), nickel (Ni), lead (Pb), titanium (Ti), and/or alloys thereof. The metal may include copper (Cu), but the present invention is not limited thereto. Each of the first and second wiring layers 121 and 122 may perform various functions according to a design. For example, the first and second wiring layers 121 and 122 may include a signal pattern, a power pattern, and a ground pattern. Each of these patterns may have various shapes such as a line, a plane, and a pad. The first and second wiring layers 121 and 122 may include an electroless plating layer (or chemical copper) and an electroplating layer (or electric copper), respectively. Alternatively, the first and second wiring layers 121 and 122 may include a metal foil (or a copper foil) and an electroplating layer (or electric copper). Alternatively, the first and second wiring layers 121 and 122 may include a metal foil (or a copper foil), an electroless plating layer (or chemical copper), and an electroplating layer (or electric copper). Instead of the electroless plating layer (or chemical copper), a sputtering layer may be included therein, or both the electroless plating layer and the sputtering layer may be included therein, if necessary.

A through-via 131 may include a metal. The metal may include copper (Cu), aluminum (Al), silver (Ag), tin (Sn), gold (Au), nickel (Ni), lead (Pb), titanium (Ti), and/or alloys thereof. The metal may include copper (Cu), but the present invention is not limited thereto. The through-via 131 may penetrate between the upper surface and the lower surface of the inorganic insulating layer 111. An upper surface and a lower surface of the through-via 131 may be substantially coplanar with the upper surface and the lower surface of the inorganic insulating layer 111. The through-via 131 may perform various functions according to a design. For example, the through-via 131 may include a ground via, a power via, and a signal via. The through-via 131 may have a substantially circular or elliptical shape on a plane, but the present disclosure is not limited thereto, and for example, the through-via 131 may have a substantially flower shape on a plane in terms of ensuring adhesion by increasing a specific surface area.

Each of the first and second connection vias 132 and 133 may include a metal. The metal may include copper (Cu), aluminum (Al), silver (Ag), tin (Sn), gold (Au), nickel (Ni), lead (Pb), titanium (Ti), and/or alloys thereof. The metal may further include copper (Cu), but the present invention is not limited thereto. Each of the first and second connection vias 132 and 133 may include a field via that fills a via hole, but may also include a conformal via disposed along a wall surface of the via hole. The first and second connection vias 132 and 133 may perform various functions according to a design. For example, the first and second connection vias 132 and 133 may include a ground via, a power via, and a signal via. The first and second connection vias 132 and 133 may have taper shapes opposite to each other on a cross-section. The first and second connection vias 132 and 133 may include an electroless plating layer (or chemical copper) and an electroplating layer (or electric copper), respectively. Instead of the electroless plating layer (or chemical copper), a sputtering layer may be included therein, or both the electroless plating layer and sputtering layer may be included therein, if necessary.

Each of the one or more first and second build-up insulating layers 141 and 151 may include an insulating material. The insulating material may include a thermosetting resin such as an epoxy resin, a thermoplastic resin such as polyimide, or materials including an inorganic filler, an organic filler, and/or glass fibers (Glass Fiber, Glass Cloth, Glass Fabric) along with these resins. For example, the insulating material may be a non-sensitive insulating material such as an Ajinomoto build-up film (ABF) or Prepreg (PPG), but the present disclosure is not limited thereto, and other polymer materials may be used. Furthermore, the insulating material may be a photosensitive insulating material such as a photoimageable dielectric (PID). The one or more first and second build-up insulating layers 141 and 151 may include substantially the same insulating material as each other, or may include different insulating materials.

Each of the one or more first and second build-up wiring layers 142 and 152 may include a metal. The metal may include copper (Cu), aluminum (Al), silver (Ag), tin (Sn), gold (Au), nickel (Ni), lead (Pb), titanium (Ti), and/or alloys thereof. The metal may include copper (Cu), but the present invention is not limited thereto. Each of the one or more first and second build-up wiring layers 142 and 152 may perform various functions according to a design. For example, the first and second build-up wiring layers 142 and 152 may include a signal pattern, a power pattern, and a ground pattern. Each of these patterns may have various shapes such as a line, a plane, and a pad. The one or more first and second build-up wiring layers 142 and 152 may include an electroless plating layer (or chemical copper) and an electroplating layer (or electric copper), respectively. Alternatively, the first and second build-up wiring layers 142 and 152 may include a metal foil (or a copper foil) and an electroplating layer (or electric copper). Alternatively, the first and second build-up wiring layers 142 and 152 may include a metal foil (or a copper foil), an electroless plating layer (or chemical copper), and an electroplating layer (or electric copper). Instead of the electroless plating layer (or chemical copper), a sputtering layer may be included therein, or both the electroless plating layer and the sputtering layer may be included therein, if necessary.

Each of the one or more first and second build-up via layers 143 and 153 may include a metal. The metal may include copper (Cu), aluminum (Al), silver (Ag), tin (Sn), gold (Au), nickel (Ni), lead (Pb), titanium (Ti), and/or alloys thereof. The metal may include copper (Cu), but the present invention is not limited thereto. Each of the one or more first and second build-up via layers 143 and 153 may include a field via that fills a via hole, but may also include a conformal via disposed along a wall surface of the via hole. The first and second build-up via layers 143 and 153 may perform various functions according to a design. For example, the first and second build-up via layers 143 and 153 may include a ground via, a power via, and a signal via. The one or more first and second build-up via layers 143 and 153 may have taper shapes opposite to each other on cross-sections. The one or more first and second build-up connection vias 143 and 153 may include an electroless plating layer (or chemical copper) and an electrolytic plating layer (or electric copper), respectively. Instead of the electroless plating layer (or chemical copper), a sputtering layer may be included therein, or both the electroless plating layer and the sputtering layer may be included therein, if necessary.

The first and second resist layers 161 and 162 may include a liquid-type or film-type solder resist, but the present disclosure is not limited thereto, and other types of insulating materials may be used. A surface treatment layer may be formed on a pattern exposed to the one or more first openings 161h and/or the one or more second openings 162h, respectively, if necessary. Alternatively, a metal bump may be formed on the pattern exposed to the one or more first openings 161h and/or the one or more second openings 162h, respectively.

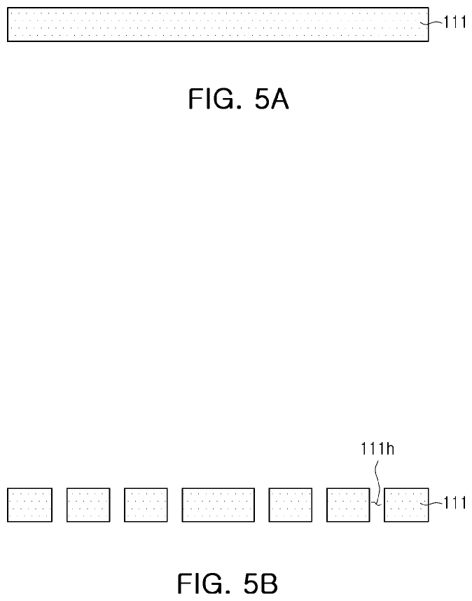

FIG. 4 is a cross-sectional view schematically illustrating a modified example of a printed circuit board of FIG. 3.

Referring to FIG. 4, a printed circuit board 100B according to the modified example may include first and second semiconductor chips 171 and 172 respectively disposed on the first resist layer 161 and respectively disposed on the uppermost first build-up wiring layer among the one or more first build-up wiring layers 142, in the printed circuit board 100A according to the above-described example embodiment. The first and second semiconductor chips 171 and 172 may be connected to at least a portion exposed through the one or more first openings 161h on the uppermost first build-up wiring layer through first and second connection members 181 and 182, respectively. The first and second semiconductor chips 171 and 172 may be electrically connected to each other through the one or more first and second build-up wiring layers 142 and 152 and the first and second wiring layers 121 and 122. An electrical connection metal 183 may be disposed on the second opening 162h of the second resist layer 162. The electrical connection metal 183 may be connected to a lowermost second build-up wiring layer among the one or more second build-up wiring layers 152 respectively exposed through the one or more second openings 162h. For example, the printed circuit board 100B according another to example embodiment may be a semiconductor package structure including a 2.xD level FCB substrate with a substantially symmetrical structure.

Each of the first and second semiconductor chips 171 and 172 may include an integrated circuit (IC) die in which hundreds to millions of elements are integrated into one chip. In this case, an integrated circuit may be a logic chip such as a central processor (e.g., a CPU), a graphics processor (e.g., a GPU), a field programmable gate array (FPGA), a digital signal processor, an encryption processor, a microprocessor, a microcontroller, an application processor (e.g., AP), an analog-digital converter, and an application-specific IC (ASIC), but the present disclosure is not limited thereto, and the integrated circuit may be memory chips such as a volatile memory (e.g., a DRAM), a non-volatile memory (e.g., an ROM), a flash memory and a high bandwidth memory (HBM), or another type such as a power management IC (PMIC). For example, the first semiconductor chip 171 may include the logic chip such as the GPU, and the second semiconductor chip 172 may include the memory chip such as the HBM.

The first and second semiconductor chips 171 and 172 may be formed based on active wafers, respectively, and in this case, silicon (Si), germanium (Ge), and gallium (GaAs) may be used as a base material for each body. Various circuits may be formed in the body. A connection pad may be formed on each body, and the connection pad may include a conductive material such as aluminum (Al) and copper (Cu). The first and second semiconductor chips 171 and 172 may be bare dies, respectively, and in this case, a metal bump may be disposed on the connection pad. The first and second semiconductor chips 171 and 172 may be packaged dies, respectively, and in this case, a rewiring layer may be additionally formed on the connection pad, and the metal bump may be disposed on the rewiring layer.

The first and second connection members 181 and 182 may be respectively formed of a low melting point metal, for example, a solder such as tin (Sn)-aluminum (Al)-copper (Cu), but this is only an example, and the present disclosure is not particularly limited thereto. Each of the first and second connection members 181 and 182 may be a ball. The first and second connection members 181 and 182 may be formed of multiple layers or a single layer, respectively. When the first and second connection members 181 and 182 are formed of multiple layers, they may include a copper column and solder, and when the first and second connection members 181 and 182 are formed of a single layer, they may include a tin-silver solder or copper, but the present disclosure is not limited thereto.

The electrical connection metal 183 is a constituent for connecting the printed circuit board 100B to a main board or another substrate of an electronic device. The electrical connection metal 183 may be disposed through an underbump metal if necessary. The electrical connection metal 183 may be formed of a conductive material, such as a solder, but this is only an example and the material is not particularly limited thereto. The electric connection metal 183 may be a ball, a pin, or the like, respectively. Each of the electrical connection metals 183 may be formed of multiple layers or a single layer. When the electrical connection metal 183 is formed of multiple layers, it may include a copper column and solder, and when the electrical connection metal 183 is formed of a single layer, it may include a tin-silver solder or copper, but the present invention is not limited thereto. There may be a plurality of electrical connection metals 183, and the number thereof is not particularly limited.

Other contents are substantially the same as described in the printed circuit board 100A according to the above-described example embodiment and the manufacturing method therefor, and redundant descriptions thereof will be omitted.

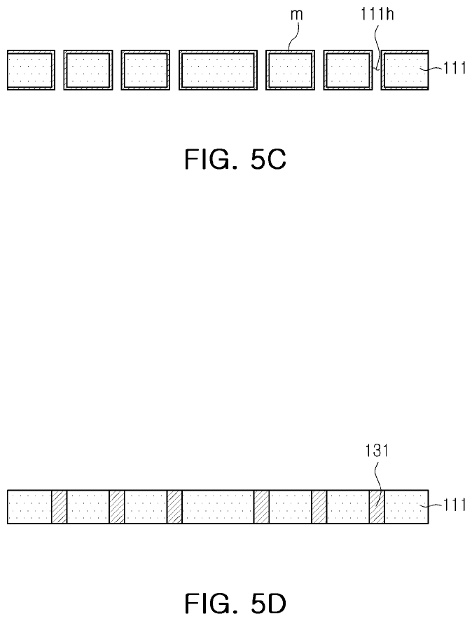

FIGS. 5A to 5H are process diagrams schematically illustrating an example of manufacturing the printed circuit board of FIG. 3.

Referring to FIGS. 5A to 5H, a manufacturing method for a printed circuit board 100A according to an example embodiment may include an operation of disposing an inorganic insulating layer 111 on a penetration portion 210H of a frame 210 having the penetration portion 210H, an operation of filling a space between an external side surface of the inorganic insulating layer 111 and a wall surface of the penetration portion 210H with a resin layer 112, an operation of stacking first and second insulating layers 113 and 114 on an upper side and a lower side of the inorganic insulating layer 111 and the resin layer 112, respectively, an operation of forming first and second wiring layers 121 and 122 on an upper side and a lower side of the core layer 110, respectively, and an operation of removing the frame 210. When such a process is used, a printed circuit board configured to form a high-density microcircuit with a high yield and low costs may be manufactured. Furthermore, a printed circuit board having excellent warpage control may be manufactured.

On the other hand, the manufacturing method for the printed circuit board 100A according to an example embodiment may further include an operation of forming a through-via 131 penetrating through the inorganic insulating layer 111 before the operation of disposing the inorganic insulating layer 111. For example, the inorganic insulating layer 111 may be disposed in the penetration portion 210H of the frame 210 in a state in which the through-via 131 is formed. Furthermore, in the operation of forming the first and second wiring layers 121 and 122, first and second connection vias 132 and 133 may be further formed which penetrate through the first and second insulating layers 113 and 114, respectively, and are connected to the first and second wiring layers 121 and 122, respectively, and come into contact with an upper surface and a lower surface of the through-via 131, respectively.

On the other hand, in the manufacturing method for the printed circuit board 100A according to an example embodiment, a tape 220 may be attached to a lower side of the frame 210, and the inorganic insulating layer 111 may be attached to the tape 220 exposed through the penetration portion 210H in the operation of disposing the inorganic insulating layer 111. In this case, the inorganic insulating layer 111 may include the glass layer or the silicon layer as described above. Furthermore, in the operation of stacking the first and second insulating layers 113 and 114, after the first insulating layer 113 is stacked on the upper side of the inorganic insulating layer 111 and the resin layer 112, the tape 220 may be removed, and then the second insulating layer 114 may be stacked on the lower side of the inorganic insulating layer 111 and the resin layer 112.

On the other hand, the manufacturing method for the printed circuit board 100A according to an example embodiment may include an operation of forming one or more first and second build-up insulating layers 141 and 151 on the first and second insulating layers 113 and 114, respectively, and an operation of forming one or more first and second build-up wiring layers 142 and 152 on or in each of the one or more first and second build-up insulating layers 113 and 114. Furthermore, in the step of forming the one or more first and second build-up wiring layers 142 and 152, one or more first and second build-up via layers 145 and 153 which penetrate through at least one of the one or more first and second build-up insulating layers 141 and 151 and are connected to at least one of the one or more first and second build-up wiring layers 142 and 152, respectively, may be further formed.

The printed circuit board 100A according to the example embodiment formed by the manufacturing method, which includes the inorganic insulating layer 111 as described above, may basically have excellent planarization, and may be advantageous for warpage control through a low coefficient of thermal expansion (CTE). Furthermore, the manufacturing process using a frame may be used to have a vertical external side surface of the inorganic insulating layer 111, and the external side surface may not be externally exposed by being covered with the resin layer 112. Furthermore, since the first and second insulating layers 113 and 114 are stacked on the inorganic insulating layer 111 and the resin layer 112, planarization may be further improved, so that it may be more advantageous to form high-density microcircuits with fine pitches. Furthermore, the number of layers of the printed circuit board 110A may be reduced and the degree of design freedom may be further increased through dielectric characteristics of the inorganic insulating layer 111, for example, the characteristics of glass having variable properties of Dk 2.5 to 11. Through the printed circuit board 100A, a flip chip board (FCB) substrate on a 2.xD level may be easily manufactured.

Hereinafter, referring to the drawings, a manufacturing method for the printed circuit board 100A according to an example will be described in more detail.

Referring to FIG. 5A, an inorganic insulating layer 111 is prepared. The inorganic insulating layer 111 may be a glass layer, and the glass layer may be in the form of a glass plate. Alternatively, the inorganic insulating layer 111 may be a silicon layer, and the silicon layer may be in the form of a silicon plate or in the form of an oxide layer formed on the silicon plate.

Referring to FIG. 5B, a penetration hole 111h is formed in the inorganic insulating layer 111. The penetration hole 111h may be formed by various methods such as laser processing, mechanical processing, or chemical processing. A plurality of penetration holes 111h may be formed.

Referring to FIG. 5C, a seed metal layer m is formed on an upper surface and a lower surface of the inorganic insulating layer 111 and a wall surface of the penetration hole 111h. The seed metal layer m may include copper (Cu), aluminum (Al), silver (Ag), tin (Sn), gold (Au), nickel (Ni), lead (Pb), titanium (Ti), and/or alloys thereof. The seed metal layer m may include copper (Cu), but the present invention is not limited thereto. The seed metal layer m may be formed by electroless plating (or chemically copper plating) or sputtering.

Referring to FIG. 5D, a through-via 131 is formed in the penetration hole 111h. The through-via 131 may be formed by performing electroplating (or electro-copper plating) on the seed metal layer m. The through-via 131 may fill the penetration hole 111h, and plating layers on the upper surface and the lower surface of the inorganic insulating layer 111 may be removed by etching.

Referring to FIG. 5E, the inorganic insulating layer 111 is disposed in the penetration hole 210H of the frame 210. For example, after attaching a tape 220 for blocking the lower side of the penetration hole 210H to the lower side of the frame 210, the inorganic insulating layer 111 may be attached to the adhesive tape 220 exposed from the penetration hole 210H. The frame 210 may include various materials such as a metal and an organic insulating material. The frame 210 may have a jig shape. The tape 220 may include polyimide (PI), but the present disclosure is not limited thereto.

Referring to FIG. 5F, the remaining space of the penetration hole 210H is filled with the resin layer 112. Next, a first insulating layer 113 is stacked on the upper side of the inorganic insulating layer 111 and the resin layer 112. In this case, planarization may proceed if necessary. The resin layer 112 may be formed by an underfill process. The first insulating layer 113 may be formed by a lamination process.

Referring to FIG. 5G, the tape 220 is removed, and the second insulating layer 114 is stacked on the lower side of the inorganic insulating layer 111 and the resin layer 112 from which the adhesive tape 220 has been removed. In this case, planarization may proceed if necessary. The second insulating layer 114 may be formed by the lamination process. The core layer 110 may be formed therethrough.

Referring to FIG. 5H, after processing via holes in the first and second insulating layers 114 and 115, the first and second wiring layers 121 and 122 and the first and second connection vias 132 and 133 are formed by a plating process. Furthermore, one or more first and second build-up insulating layers 141 and 151, one or more first and second build-up wiring layers 142 and 152, and one or more first and second build-up via layers 143 and 153 are formed on the first and second insulating layers 114 and 115 through a build-up process and the plating process. Furthermore, first and second resist layers 161 and 162 are formed on the one or more first and second build-up insulation layers 141 and 151 by the lamination process or a coating process. Furthermore, the frame 210 is removed. The frame 210 may be removed by a singulation process. The printed circuit board 100A according to the above-described example embodiment may be manufactured through a series of processes.

Other contents are substantially the same as those described in the printed circuit board 100A according to the above-described example embodiments, and redundant descriptions thereof will be omitted.

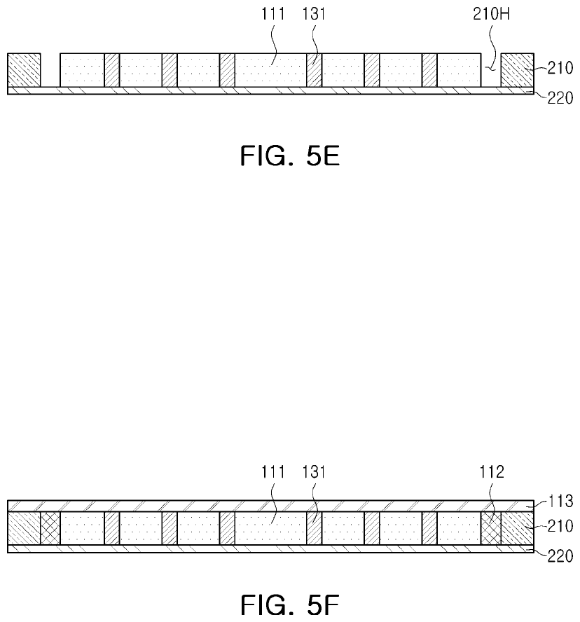

FIGS. 6A and 6B are process diagrams schematically illustrating an example of disposing a plurality of inorganic insulating layers on a frame having a plurality of penetration portions.

Referring to FIGS. 5A and 5B, a frame 210 may have a plurality of penetration portions 210H, and a plurality of inorganic insulating layers 111 may be disposed in the plurality of penetration portions 210H, respectively. Each of the plurality of inorganic insulating layers 111 may have a through-via 131 formed thereon as described above. The plurality of inorganic insulating layers 111 may be disposed using the tape 220 as described above. Then, a plurality of printed circuit board 100A units may be manufactured using the processes of FIGS. 5F to 5G described above, and a plurality of printed circuit boards 100A may be obtained through the singulation process. In this manner, the plurality of printed circuit boards 100A may be manufactured in a single process.

Other contents are substantially the same as described in the printed circuit board 100A according to the above-described example embodiment and the manufacturing method therefor, and redundant descriptions thereof will be omitted.

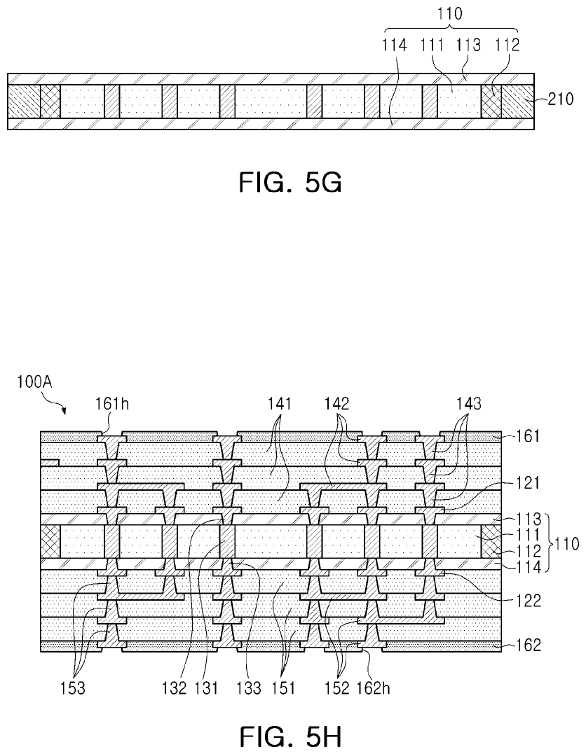

FIG. 7 is a cross-sectional view schematically illustrating the other example of a printed circuit board.

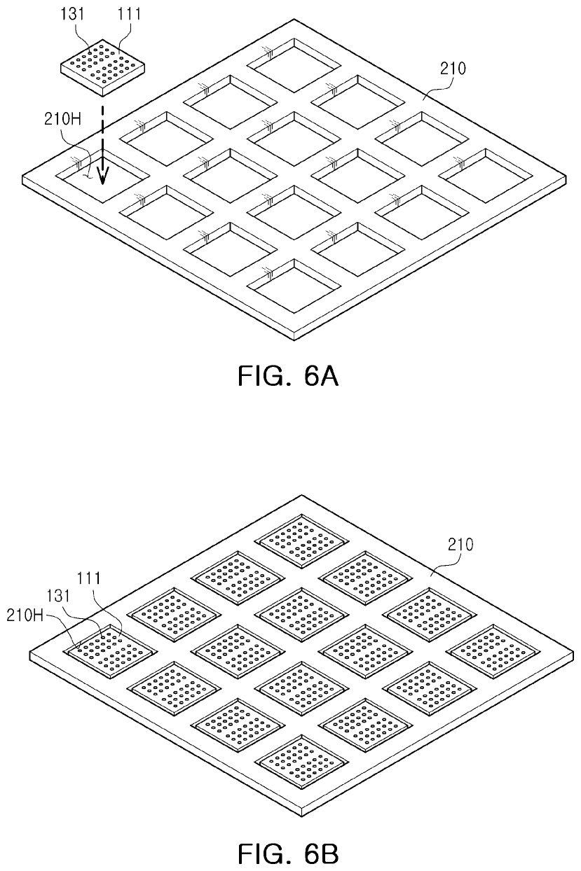

FIG. 8 is a cross-sectional view schematically illustrating a modified example of a printed circuit board of FIG. 7.

Referring to the drawings, a printed circuit board 100C according to the other example embodiment and a printed circuit board 100D according to the modified example thereof may have different numbers of layers of the one or more first and second build-up insulating layers 141 and 151 in the printed circuit board 100A according to the above-described example embodiment and the printed circuit board 100B according to the modified example thereof. For example, the number of layers of the one or more first build-up insulating layers 141 may be greater than the number of layers of the one or more second build-up insulating layers 151. Furthermore, the number of layers of the one or more first build-up wiring layer 142 may be greater than the number of layers of the one or more second build-up wiring layers 152. Furthermore, the number of one or more first build-up via layers 143 may be greater than the number of one or more second build-up via layers 153. If necessary, the one or more second build-up insulating layers 151, the one or more second build-up wiring layers 152, and the one or more second build-up via layers 153 may be omitted. For example, printed circuit boards 100C according to the other example embodiment and 100D according to the modified example thereof may be a 2.xD level FCB substrate with an asymmetric structure and a semiconductor package structure including the same.

Other contents are substantially the same as those described in the printed circuit board 100A according to the above-described example embodiment, the printed circuit board 100B according to the modified example thereof, and the manufacturing method therefor, and redundant descriptions thereof will be omitted.

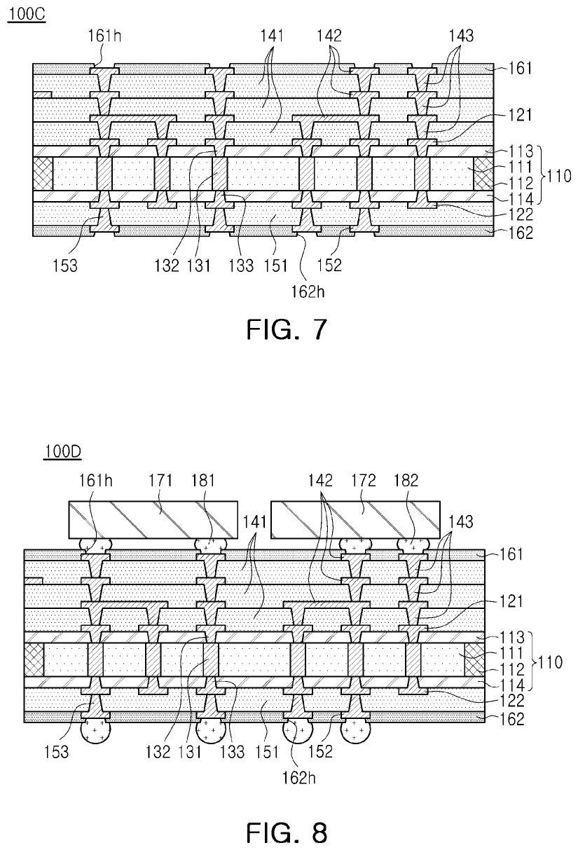

FIG. 9 is a cross-sectional view schematically illustrating another example of a printed circuit board;

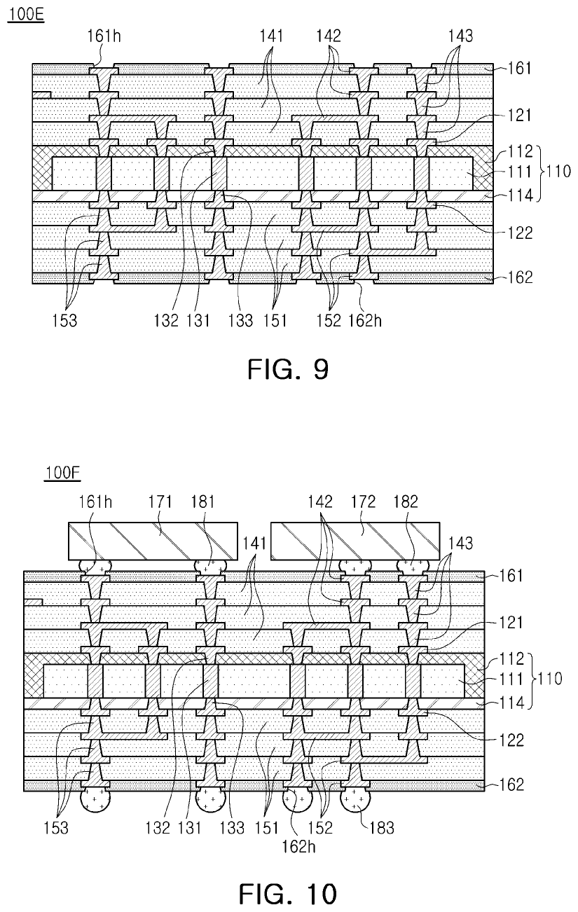

FIG. 10 is a cross-sectional view schematically illustrating a modified example of a printed circuit board of FIG. 9.

Referring to the drawings, a printed circuit board 100E according to another example and a printed circuit board 100F according to a modified example thereof may be configured such that the first insulating layer 113 may be omitted and the resin layer 112 may be disposed thereon instead of the first insulating layer 113 in the printed circuit board 100A according to the embodiment and the printed circuit board 100B according to the modified example described above, respectively. For example, the resin layer 112 may be extended to cover an upper surface of the inorganic insulating layer 111. Accordingly, the first connection via 132 may penetrate through the resin layer 112. For example, the printed circuit board 100E according to another example and the printed circuit board 100F according to a modified example thereof may be a 2.xD level FCB substrate in which the core layer 110 has an asymmetric structure and a semiconductor package structure including the same.

Other contents are substantially the same as described in the printed circuit board 100A according to the above-described example embodiment, and the printed circuit board 100B according to the modified example, and redundant description thereof will be omitted.

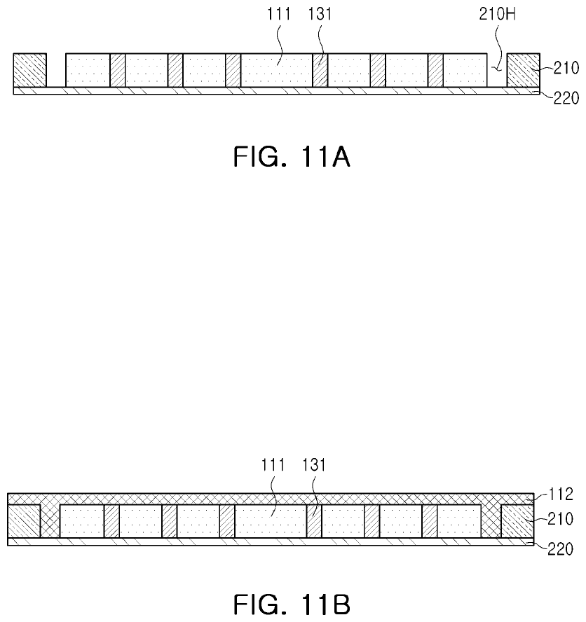

FIGS. 11A to 11D are process diagrams schematically illustrating an example of manufacturing the printed circuit board of FIG. 9.

Referring to the drawings, a manufacturing method for a printed circuit board 100E according to another example embodiment may be performed such that in the operation of filling a space between an external side surface of the inorganic insulating layer 111 and a wall surface of the penetration portion 210H with the resin layer 112, an upper side of the frame 210 and the inorganic insulating layer 111 may be covered with the resin layer 112, in the manufacturing method for the printed circuit board 100A according to the above-described example embodiment. Additionally, in the operation of forming the first and second wiring layers 121 and 122, the first connection via 132 may be formed by penetrating through the resin layer 112.

Hereinafter, a method manufacturing for a printed circuit board 100E according to another example embodiment will be described in more detail with reference to the drawings.

Referring to FIG. 11A, the inorganic insulating layer 111 is disposed in the penetration hole 210H of the frame 210. For example, substantially the same process as in FIGS. 5A to 5E described above and FIGS. 6A and 6B described above may be used.

Referring to FIG. 11B, a remaining space of the penetration hole 210H is filled with the resin layer 112. Furthermore, an upper side of the frame 210 and the inorganic insulating layer 111 is covered with a resin layer 112. In this case, planarization may be performed as needed.

Referring to FIG. 11C, the tape 220 is removed, and the second insulating layer 114 is stacked on a lower side of the inorganic insulating layer 111 and the resin layer 112 from which the tape 220 was removed. In this case, planarization may be performed as needed. The core layer 110 may be formed therethrough.

Referring to FIG. 11D, after processing via holes in the resin layer 112 and the second insulating layer 115, the first and second wiring layers 121 and 122 and the first and second connection vias 132 and 133 are formed through a plating process. Furthermore, one or more first and second build-up insulating layers 141 and 151, one or more first and second build-up wiring layers 142 and 152, and one or more first and second build-up via layers 143 and 153 are formed through a build-up process and a plating process on the core layer 110. Furthermore, the first and second resist layers 161 and 162 are formed on one or more of the first and second build-up insulating layers 141 and 151 through a lamination process or a coating process. Furthermore, the frame 210 is removed. The frame 110 may be removed through a singulation process or the like. A printed circuit board 100E according to another example embodiment described above may be manufactured through a series of processes.

Other contents are substantially the same as those described in the printed circuit board 100E according to another example embodiment described above, and the manufacturing method for the printed circuit board 100A according to the above-described example, and redundant descriptions thereof will be omitted.

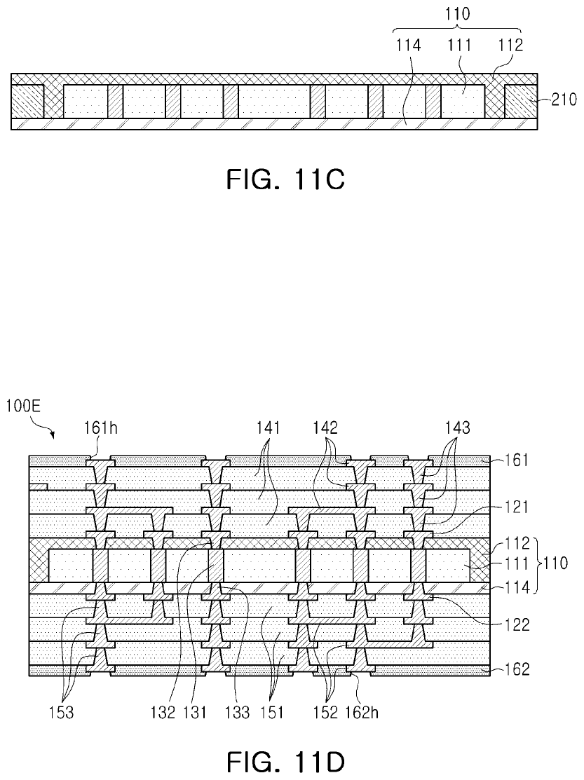

FIG. 12 is a cross-sectional view schematically illustrating another example embodiment of a printed circuit board.

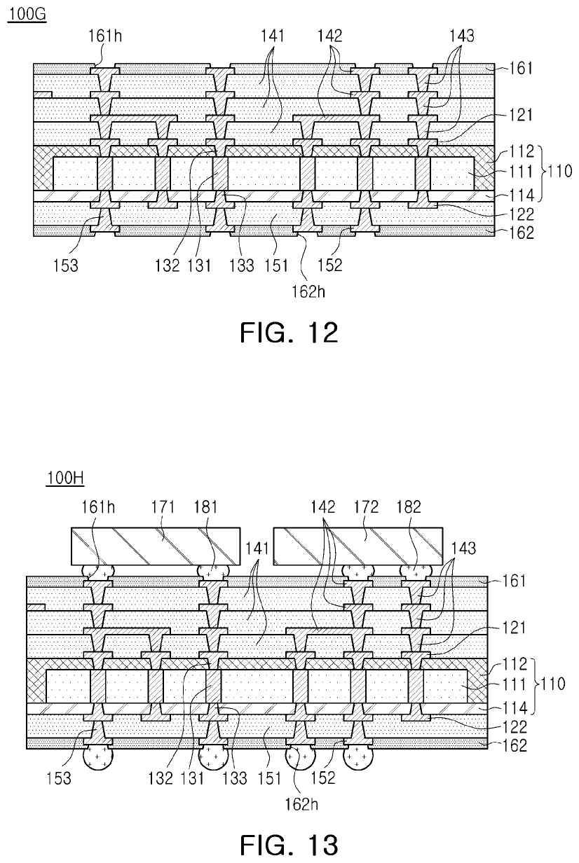

FIG. 13 is a cross-sectional view schematically illustrating a modified example of the printed circuit board of FIG. 12.

Referring to the drawings, a printed circuit board 100G according to another example embodiment and a printed circuit board 100H according to a modified example thereof may be configured such that one or more first and second build-up insulating layers 141 and 151 may have different numbers of layers in the printed circuit board 100E according to the example embodiment and the printed circuit board 100F according to the modified example described above, respectively. For example, the number of layers of one or more first build-up insulating layers 141 may be greater than the number of layers of one or more second build-up insulating layers 151. Furthermore, the number of layers of one or more first build-up wiring layers 142 may be greater than the number of layers of one or more second build-up wiring layers 152. Furthermore, the number of one or more first build-up via layers 143 may be greater than the number of one or more second build-up via layers 153. If necessary, the one or more second build-up insulating layers 151, the one or more second build-up wiring layers 152, and the one or more second build-up via layers 153 may be omitted. For example, the printed circuit board 100G according to another example embodiment and the printed circuit board 100H according to the modified example thereof may be a 2.xD level FCB substrate having an asymmetric structure and a semiconductor package structure including the same.

Other contents are substantially the same as those described in the printed circuit board 100E according to another example embodiment, the printed circuit board 100F according to the modified example thereof, and the manufacturing method therefor, and redundant descriptions thereof will be omitted.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of approximately filling, and may include, for example, a case in which some pores or voids exist. Furthermore, a surrounding expression may include not only completely surrounding but also approximately surrounding. In addition, exposure may include not only complete exposure but also partial exposure, and the exposure may refer to exposure from burying a corresponding configuration. For example, an opening exposing the pad may be exposing the pad from the resist layer, and a surface treatment layer may be further disposed on the exposed pad.

In the present disclosure, substantially, determination may be performed by including a process error or a positional deviation occurring in a manufacturing process, and an error during measurement. For example, the expression ‘substantially vertical’ may include not only a completely vertical case but also an approximately vertical case. Furthermore, being substantially coplanar may include not only a case in which components exist on the completely same plane, but also a case in which components exist on approximately the same plane.

In the present disclosure, the same insulating material may have a meaning including the same type of insulating material as well as a case of completely the same insulating material. Accordingly, the compositions of the insulating materials are substantially identical to each other, but specific composition ratios thereof may be slightly different from each other.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, a lower side, a lower portion, and a lower surface are used to refer to a downward direction with respect to a cross-section of a drawing, and an upper side, an upper portion, and an upper surface are used to refer to an opposite direction thereof. However, this defines the direction for convenience of explanation, and the scope of the rights of the claims is not particularly limited by the description of such a direction, and the concept of upper and lower portions may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in particular example embodiment t are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board comprising:
a core layer including an inorganic insulating layer, a resin layer covering at least a portion of an external side surface of the inorganic insulating layer, and a second insulating layer covering at least a portion of a lower surface of each of the inorganic insulating layer and the resin layer and having an interlayer boundary with the resin layer;
a first wiring layer disposed on an upper surface of the core layer; and
a second wiring layer disposed on a lower surface of the core layer,
wherein the external side surface of the inorganic insulating layer is substantially perpendicular to at least one of the upper surface and the lower surface of the inorganic insulating layer.

2. The printed circuit board according to claim 1, wherein the core layer further includes a first insulating layer covering at least a portion of an upper surface of each of the inorganic insulating layer and the resin layer and having an interlayer boundary with the resin layer.

3. The printed circuit board according to claim 2, wherein the upper surface and the lower surface of the inorganic insulating layer are substantially coplanar with the upper surface and the lower surface of the resin layer.

4. The printed circuit board according to claim 2, wherein the resin layer includes an organic insulating material different from those of the first and second insulating layers.

5. The printed circuit board according to claim 2, further comprising:
a through-via configured to penetrate through the inorganic insulating layer; and
a first connection via configured to penetrate through the first insulating layer, connected to the first wiring layer, and coming into contact with an upper surface of the through-via,
a second connection via configured to penetrate through the second insulating layer, connected to the second wiring layer, and coming into contact with a lower surface of the through-via,
wherein the first and second connection vias are tapered in opposite directions.

6. The printed circuit board according to claim 1, wherein the resin layer is disposed to extend to cover at least a portion of the upper surface of the inorganic insulating layer.

7. The printed circuit board according to claim 6, further comprising:
a through-via configured to penetrate through the inorganic insulating layer;
a first connection via configured to penetrate through the resin layer, connected to the first wiring layer, and coming into contact with an upper surface of the through-via; and
a second connection via configured to penetrate through the second insulating layer, connected to the second wiring layer, and coming into contact with a lower surface of the through-via,
wherein the first and second connection vias are tapered in opposite directions.

8. The printed circuit board according to claim 1, wherein the inorganic insulating layer includes a glass layer or a silicon layer.

9. The printed circuit board according to claim 1, further comprising:
one or more first build-up insulating layers disposed on the upper surface of the core layer and configured to cover the first wiring layer;
one or more first build-up wiring layers disposed on or in the one or more first build-up insulating layers;
one or more first build-up via layers each penetrating through at least one of the one or more first build-up insulating layers;
one or more second build-up insulating layers disposed on the lower surface of the core layer and configured to cover the second wiring layer;
one or more second build-up wiring layers disposed on or in the one or more second build-up insulating layers; and
one or more second build-up via layers each penetrating through at least one of the one or more second build-up insulating layers,
wherein the one or more first and second build-up via layers are tapered in opposite directions.

10. The printed circuit board according to claim 9, wherein the one or more first build-up insulating layers have a greater number of layers than the one or more second build-up insulating layers.

11. The printed circuit board according to claim 8, further comprising:
a first resist layer disposed on the one or more first build-up insulation layers and having one or more first openings configured to respectively expose at least a portion of an uppermost first build-up wiring layer among the one or more first build-up wiring layers;
a second resist layer disposed on the one or more second build-up insulation layers and having one or more second openings configured to respectively expose at least a portion of a lowermost second build-up wiring layer of the one or more second build-up wiring layers; and
one or more semiconductor chips disposed on the first resist layer, respectively, and connected to at least a portion of the uppermost first build-up wiring layer exposed through the one or more first openings, respectively.

12. A manufacturing method for a printed circuit board, the method comprising:
disposing an inorganic insulating layer on a penetration portion of a frame having the penetration portion;
filling at least a portion of a space between an external side surface of the inorganic insulating layer and a wall surface of the penetration portion with a resin layer;
forming a core layer by stacking a second insulating layer on a lower side of the inorganic insulating layer and the resin layer;
forming first and second wiring layers on an upper side and a lower side of the core layer, respectively, and
removing the frame.

13. The manufacturing method for a printed circuit board of claim 12, wherein the forming a core layer comprises:
further stacking a first insulating layer on an upper side of the inorganic insulating layer and the resin layer.

14. The manufacturing method for a printed circuit board of claim 13, further comprising:
before the disposing an inorganic insulating layer,
forming a through-via penetrating through the inorganic insulating layer,
wherein in the forming first and second wiring layers, first and second connection vias are further formed which penetrate through the first and second insulating layers, respectively, are connected to the first and second wiring layers, respectively, and come into contact with an upper surface and a lower surface of the through-via, respectively.

15. The manufacturing method for a printed circuit board of claim 12, wherein in the filling at least a portion of a space between an external side surface of the inorganic insulating layer and a wall surface of the penetration portion with a resin layer, an upper side of the frame and the inorganic insulating layer is covered with the resin layer.

16. The manufacturing method for a printed circuit board of claim 15, further comprising:
before the disposing an inorganic insulating layer,
forming a through-via penetrating through inorganic insulating layer,
wherein in the forming first and second wiring layers, first and second connection vias are further formed which penetrate through the resin layer and the second insulating layer, respectively, are connected to the first and second wiring layers, respectively, and come into contact with an upper surface and a lower surface of the through-via, respectively.

17. The manufacturing method for a printed circuit board of claim 12, wherein in the disposing an inorganic insulating layer, the inorganic insulating layer includes a glass layer or a silicon layer.

18. The manufacturing method for a printed circuit board of claim 12, wherein in the disposing an inorganic insulating layer, the frame has a plurality of penetration portions, and the inorganic insulating layer is disposed on each of the plurality of penetration portions.

19. The manufacturing method for a printed circuit board of claim 12, further comprising:
after the forming first and second insulating layers,
forming one or more first and second build-up insulating layers on the first and second insulating layers, respectively,
forming one or more first and second build-up wiring layers on or in each of the one or more first and second build-up insulating layers; and
forming one or more first and second build-up via layers on each of the one or more first and second build-up insulating layers.

20. The manufacturing method for a printed circuit board of claim 19, further comprising:
after the forming first and second wiring layers,
forming a first resist layer having one or more first openings each exposing at least a portion of a first build-up wiring layer disposed on an uppermost side of the one or more first build-up wiring layers, on the one or more first build-up insulating layers;
forming a second resist layer having one or more second openings each exposing at least a portion of a second build-up wiring layer disposed on a lowermost side of the one or more second build-up wiring layers, on the one or more second build-up insulating layers; and
disposing one or more semiconductor chips respectively connected to at least a portion of the uppermost first build-up wiring layer exposed through the one or more first openings on the first resist layer.

21. The manufacturing method for a printed circuit board of claim 12, wherein the frame is removed by a singulation process so that the printed circuit board is separated from a combined structure including the frame and the printed circuit board.

22. A printed circuit board comprising:
an insulating body in which a glass layer is embedded, and including a plurality of insulating layers disposed on and below the glass layer;
a plurality of wiring layers embedded in the insulating body and disposed on and below the glass layer; and
a plurality of via layers embedded in the insulating layer and the glass layer to connect the plurality of wiring layers on different levels to each other,
wherein a material of the insulating body in contact with a side surface of the glass layer and a material of the insulating body in contact with an upper surface or a lower surface of the glass layer are different from each other.

23. The printed circuit board according to claim 22, wherein the material of the insulating body in contact with the side surface of the glass layer includes a resin layer comprising an underfill or an epoxy molding compound (EMC).

24. The printed circuit board according to claim 22, wherein the material of the insulating body in contact with the upper surface or the lower surface of the glass layer comprises at least one of an Ajinomoto build-up film (ABF), a photo imageable dielectric (PID), and a bonding sheet (BS).

25. The printed circuit board according to claim 22, wherein a through-via, among the plurality of via layers, penetrates through the glass layer and is connected to another via among the plurality of via layers.

26. The printed circuit board according to claim 22, wherein vias, among the plurality of via layers, disposed on or below the glass layer, have a tapered structure tapered in a direction toward the glass layer.

27. The printed circuit board according to claim 22, wherein the number of wiring layers among the plurality of wiring layers disposed on the glass layer is different the number of wiring layers among the plurality of wiring layers disposed below the glass layer.

28. The printed circuit board according to claim 22, wherein the number of wiring layers among the plurality of wiring layers disposed on the glass layer is the same as the number of wiring layers among the plurality of wiring layers disposed below the glass layer.
